(19) United States
(12) Patent Application Publication
(10) Pub. No.: US 2002/0088398 A1
(43) Pub. Date: Jul. 11, 2002

(54) Teos deposition apparatus for semiconductor manufacture processes

(75) Inventors: Chin-Cheng Hsieh, Taoyuan (TW); Yung-Nan Liu, Hsinchu (TW); Wan-Ching Chang, Hsinchu (TW); M. G. Chen, Hsinchu (TW)

Correspondence Address: Daniel R. McClure, THOMAS, KAYDEN, HORSTEMEYER & RISLEY, L.L.P, 100 Galleria Parkway, N.W., Suite 1750, Atlanta, GA, 30339-5948, US

(73) Assignee: Mosel Vitelic Inc., Hsin-Chu (TW)

(21) Appl. No.: 09/757,522

(22) Filed: Jan. 9, 2001

(51) Int. Cl. C23C 16/00

(52) U.S. Cl. 118/715

(57) ABSTRACT

Disclosed is an improved tetraethylorthosilicate (TEOS) deposition apparatus for semiconductor manufacture processes, in which the apparatus comprises a furnace chamber for performing TEOS deposition and an exhaust pipe line connected with the furnace chamber for discharging a gas from the furnace chamber, and the exhaust pipe line is connected with a main valve, an automatic pressure control (APC) valve and a pump in sequence. The improvement is characterized in that the exhaust pipe line further connects a disc trap between the main valve and APC valve for filtering the gas in the exhaust pipe line. With the insertion of the disc trap in the exhaust pipe line to collect and filter TEOS deposition from the gas in the exhaust pipe line, failure and wearing of the APC valve caused by TEOS due to temperature variations are prevented, thereby increasing the lifetime of the APC valve and reducing the failure possibility.

### FIELD OF THE INVENTION

The present invention relates generally to a semiconductor manufacture apparatus, and more particularly, to an improvement of a tetraethylorthosilicate (TEOS) deposition apparatus for increasing the lifetime of the automatic pressure control (APC) valve thereof.

### BACKGROUND OF THE INVENTION

TEOS is an organic silicide containing silicon and oxygen, and it is a viscous material under the room temperature and normal pressure. When TEOS is to be used, it is heated preferably to a temperature between 50-120° C. to enhance saturated vapor pressure, and in such a case, it won't stick to an interface. TEOS is frequently used in semiconductor manufacture processes. FIG. 1 shows a TEOS deposition apparatus in an ordinary semiconductor manufacture process. As shown, the TEOS gas is heated in a furnace chamber 10 to form silicon dioxide deposited on wafers 101. During the deposition, a pump 50 is connected with the furnace chamber 10 to maintain a stable laminar flow in the furnace chamber 10. After deposition reaction, the TEOS gas is discharged out of the furnace chamber 10 through an exhaust 11, at this time, the discharged gas is at a temperature of about 710° C. After passing through the furnace chamber 10, the discharged gas is cooled and filtered by a cold trap 20 which intercepts and traps particles that have not been deposited during in the furnace chamber 10 by the low-temperature (about room temperature) surface thereof. Then the gas is filtered again and sent to the pump by a main valve 30 through an APC valve 40 that is about 1 meter away from the main valve 30. At this stage, the exhaust pipe line 11 won't be heated any more.

The resultant gases after deposition reaction comprises TEOS which is not completely reacted and gases generated by the reaction, such as Carbon Dioxide (CO₂), organic compounds and Organic Silicide (CₓH_{y}Si). Thereafter, when the gas is discharged from the furnace chamber 10, it is at a high temperature (about 710° C.). After trapping and filtering of the cold trap 20 (about 33° C.), the temperature inside the exhaust pipe line 11 is very different from that outside the exhaust pipe line 11, resulting in a lot of deposition or poor reaction. The crystallized TEOS would adhere to the APC valve 40 and cause abnormal operation of the latter and pressure shift, such that the pump 50 cannot smoothly exhaust the remaining gases. Therefore, maintenance is increased and malfunction is frequently occurred, thereby increasing the cost and influencing the yield.

In the prior art TEOS manufacture process, since compositions of TEOS and therefore its characteristics are affected by temperature variations so that the APC valve cannot normally operate, it is desired an improved TEOS deposition apparatus to increase the lifetime of the APC valve.

### SUMMARY OF THE INVENTION

An object of the present invention is to overcome the above problem of adhesion of crystalline TEOS to the APC valve in a TEOS deposition apparatus. According to the present invention, a disc trap is inserted in the exhaust pipe line between the main valve and the APC valve of the TEOS deposition apparatus. After TEOS is discharged from the furnace chamber of the TEOS deposition apparatus, it passes through the cold trap and the main valve. Then it is filtered by various discs in the disc trap such that the remaining deposition due to temperature decrease and incomplete reaction is adhered to surfaces of the discs of the disc trap, thus the APC valve is prevented from being clogged. Therefore, deposition of crystalline TEOS, which would cause malfunction and wearing, is avoided, the lifetime of the APC valve is enhanced, and the cost thereof is reduced.

### BRIEF DESCRIPTION OF THE DRAWINGS

These and other objects, features and advantages of the present invention will become apparent to those skilled in the art upon consideration of the following description of the preferred embodiments of the present invention taken in conjunction with the accompanying drawings, in which:

FIG. 1 is a view showing a conventional TEOS deposition for semiconductor manufacture processes apparatus;

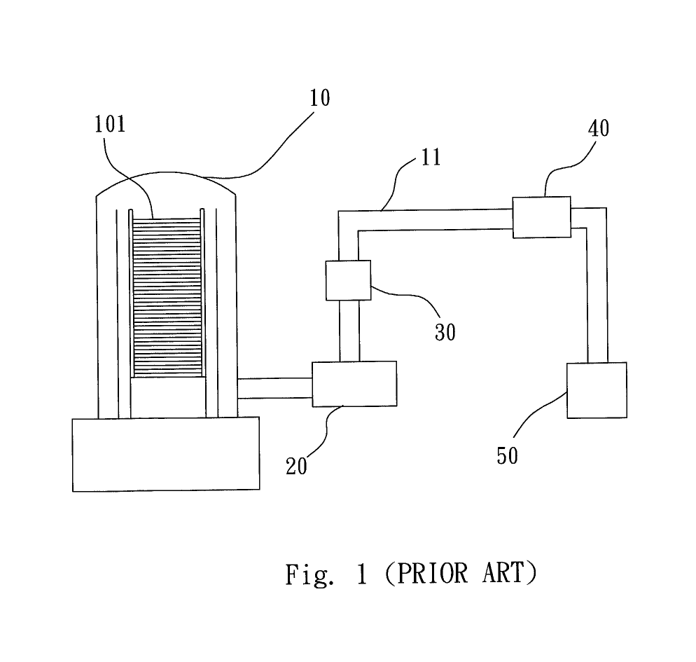

FIG. 2 is a view showing a TEOS deposition for semiconductor manufacture processes apparatus according to one embodiment of the present invention; and

FIG. 3 is a view showing a disc trap of the present invention.

### DETAILED DESCRIPTION

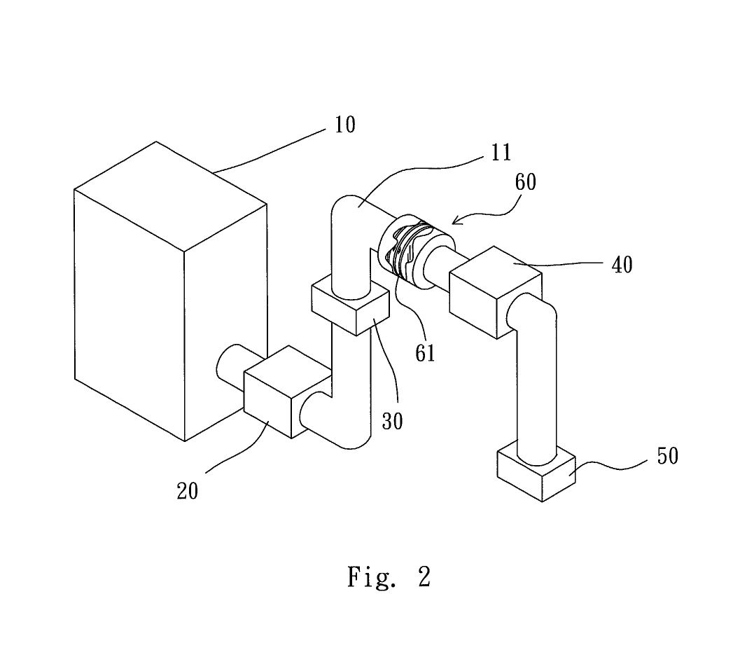

FIG. 2 shows a preferred embodiment of the present invention, by which in a TEOS deposition process, reaction gas is introduced into a furnace chamber 10 and heated to form silicon dioxide deposited on wafers disposed in the furnace chamber 10. During the deposition process, a pump 50 is operated to maintain a stable laminar flow in the furnace chamber 10. The gas is discharged from the furnace chamber 10 through an exhaust pipe line 11 and then delivered to a main valve 30 through a cold trap 20 that prevents the remaining reactants from completely flowing into the main valve 30 to clog the main valve 30. After the main valve 30, the discharged gas is not heated in the exhaust pipe line 11. To avoid characteristics change of the discharged gas due to temperature lowering, especially due to excessively low temperature which would cause crystallization and clog the APC valve 40, a disc trap 60 is provided in front of the APC valve 40 in the exhaust pipe line 11. The disc trap 60 contains a plurality of laminated discs 61. The discharged gas is converted into viscous TEOS due to temperature change and introduced into the disc trap 60 such that the depositions remained in the discharged gas would adhere to the respective discs 61, thereby decreasing the depositions on the APC valve 40 so as to reduce the frequencies of maintenance and lengthen the lifetime of the APC valve 40. Further, pressure in the exhaust pipe line 11 can be accurately detected and the pump 50 can smoothly discharge the gas. Thus, the failure possibility is reduced and the cost is decreased.

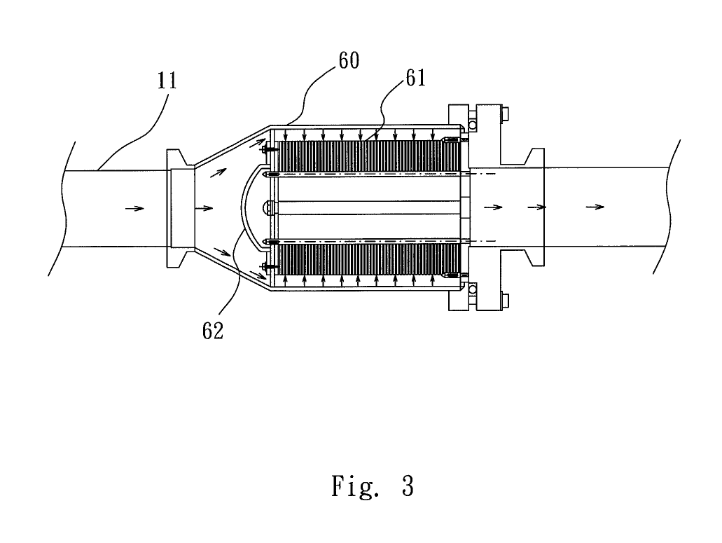

FIG. 3 shows the disc trap 60 of the present invention. The plurality of laminated discs 61 are provided in the disc trap 60. The outermost disc is closed by a partition 62 such that the gas in the exhaust pipe line 11 cannot directly enter the center of discs 61 but pass by the disc 61. When the gas passes by the respective discs 61, the reactants therein would adhere to the discs 61, which also facilitates cleaning of the discs 61 for repetitive use. Conventionally, in the case of an ordinary filter, when a reaction gas flow outwardly, reactants would adhere to inner wall of the filter, and cleaning operation is difficult. Therefore, filtering effect is poor and repetitive use is deteriorated. In addition, an APC valve will be clogged and cannot be smoothly operated in such a case.

While the present invention has been described in conjunction with preferred embodiment thereof, it is evident that many alternatives, modifications and variations will be apparent to those skilled in the art. Accordingly, it is intended to embrace all such alternatives, modifications and variations that fall within the spirit and scope thereof as set forth in the appended claims.

What is claimed is:

1. In a tetraethylorthosilicate (TEOS) deposition apparatus for semiconductor manufacture processes, the apparatus comprising:
a furnace chamber for performing TEOS deposition; and
an exhaust pipe line connected with the furnace chamber for discharging a gas from the furnace chamber, the exhaust pipe line connecting a main valve, an automatic pressure control (APC) valve and a pump in sequence;
the improvement characterized in that the exhaust pipe line further connects a trap between the main valve and APC valve for filtering the gas in the exhaust pipe line.

2. The apparatus according to claim 1, wherein the trap is a disc trap.
